(19) United States
(12) Patent Application Publication
(10) Pub. No.: US 2026/0240009 A1
(43) Pub. Date: Aug. 13, 2026

(54) SEMICONDUCTOR APPARATUS

(71) Applicant: SHINKO ELECTRIC INDUSTRIES CO., LTD., Nagano (JP)

(72) Inventor: Kenichi KOI, Nagano (JP)

(21) Appl. No.: 19/532,177

(22) Filed: Feb. 6, 2026

(30) Foreign Application Priority Data
Feb. 13, 2025 (JP) 2025-021436

(51) Int. Cl. H10W 70/63; H10W 90/10

(52) U.S. Cl. CPC H10W 70/63; H10W 90/10

(57) ABSTRACT

A semiconductor apparatus includes a first structure, a second structure disposed alongside the first structure, a third structure stacked on the first structure and the second structure, a first interconnect member stacked on a lower side of the first structure, and a second interconnect member stacked on a lower side of the second structure, wherein the first structure includes a first semiconductor device having a first electrode and a second electrode and a first interconnect, wherein the second structure includes a second semiconductor device having a third electrode and a fourth electrode and a second interconnect, wherein the third structure includes a third interconnect, and wherein the first interconnect member is a part of a path that electrically connects the second electrode and the third interconnect, and the second interconnect member is a part of a path that electrically connects the fourth electrode and the first interconnect.

### CROSS-REFERENCE TO RELATED APPLICATIONS

The present application is based on and claims priority to Japanese Patent Application No. 2025-021436 filed on February 13, 2025, with the Japanese Patent Office, the entire contents of which are incorporated herein by reference.

### FIELD

The disclosures herein relate to semiconductor apparatuses.

### BACKGROUND

A semiconductor apparatus as known in the art may be configured such that a semiconductor device is attached to a resin film via an adhesive layer, and an interconnect layer is formed on the surface of the resin film opposite to the adhesive layer (see Patent Document 1, for example).

A semiconductor apparatus having a low-inductance multilayer structure with a plurality of semiconductor devices may preferably have a structure capable of easily connecting the semiconductor devices to one another.

### Related-Art Document

[Patent Document] Japanese Laid-Open Patent Publication No. 2021-52055

### SUMMARY

According to an aspect of the embodiment, a semiconductor apparatus includes a first structure, a second structure disposed alongside the first structure, a third structure stacked on an upper side of the first structure and an upper side of the second structure, a first interconnect member stacked on a lower side of the first structure, and a second interconnect member stacked on a lower side of the second structure, wherein the first structure includes a first insulating substrate, a first semiconductor device having a first electrode and a second electrode disposed opposite the first electrode in a thickness direction, the first semiconductor device being bonded to a lower surface of the first insulating substrate via a first adhesive layer with the first electrode facing the first insulating substrate, and a first interconnect disposed on an upper surface of the first insulating substrate and electrically connected to the first electrode via a first via interconnect penetrating the first insulating substrate and the first adhesive layer, wherein the second structure includes a second insulating substrate, a second semiconductor device having a third electrode and a fourth electrode disposed opposite the third electrode in a thickness direction, the second semiconductor device being bonded to a lower surface of the second insulating substrate via a second adhesive layer with the third electrode facing the second insulating substrate, and a second interconnect disposed on an upper surface of the second insulating substrate and electrically connected to the third electrode via a second via interconnect penetrating the second insulating substrate and the second adhesive layer, wherein the third structure includes a third insulating substrate, a lower surface of which is bonded to an upper surface of the first interconnect and an upper surface of the second interconnect through a third adhesive layer, and a third interconnect disposed on an upper surface of the third insulating substrate, and wherein the first interconnect member is a part of a path that electrically connects the second electrode and the third interconnect, and the second interconnect member is a part of a path that electrically connects the fourth electrode and the first interconnect.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of a semiconductor apparatus according to a first embodiment;

FIG. 2 is a drawing illustrating an example of a basic circuit of the semiconductor apparatus according to the first embodiment;

FIG. 3 is a drawing illustrating a current flow in the semiconductor apparatus according to the first embodiment;

FIGS. 4A and 4B are drawings illustrating an example of a manufacturing process of the semiconductor apparatus according to the first embodiment;

FIGS. 5A and 5B are drawings illustrating the example of the manufacturing process of the semiconductor apparatus according to the first embodiment;

FIGS. 6A and 6B are drawings illustrating the example of the manufacturing process of the semiconductor apparatus according to the first embodiment;

FIGS. 7A and 7B are drawings illustrating the example of the manufacturing process of the semiconductor apparatus according to the first embodiment;

FIGS. 8A and 8B are drawings illustrating the example of the manufacturing process of the semiconductor apparatus according to the first embodiment;

FIGS. 9A and 9B are drawings illustrating the example of the manufacturing process of the semiconductor apparatus according to the first embodiment;

FIGS. 10A and 10B are drawings illustrating the example of the manufacturing process of the semiconductor apparatus according to the first embodiment; and

FIGS. 11A and 11B are drawings illustrating the example of the manufacturing process of the semiconductor apparatus according to the first embodiment.

### DESCRIPTION OF EMBODIMENTS

In the following, embodiments will be specifically described with reference to the accompanying drawings. In the specification and the drawings, components having substantially the same functional configuration may be referred to by the same reference numeral, and a duplicate description thereof may be omitted.

### First Embodiment

### Structure of Semiconductor Apparatus

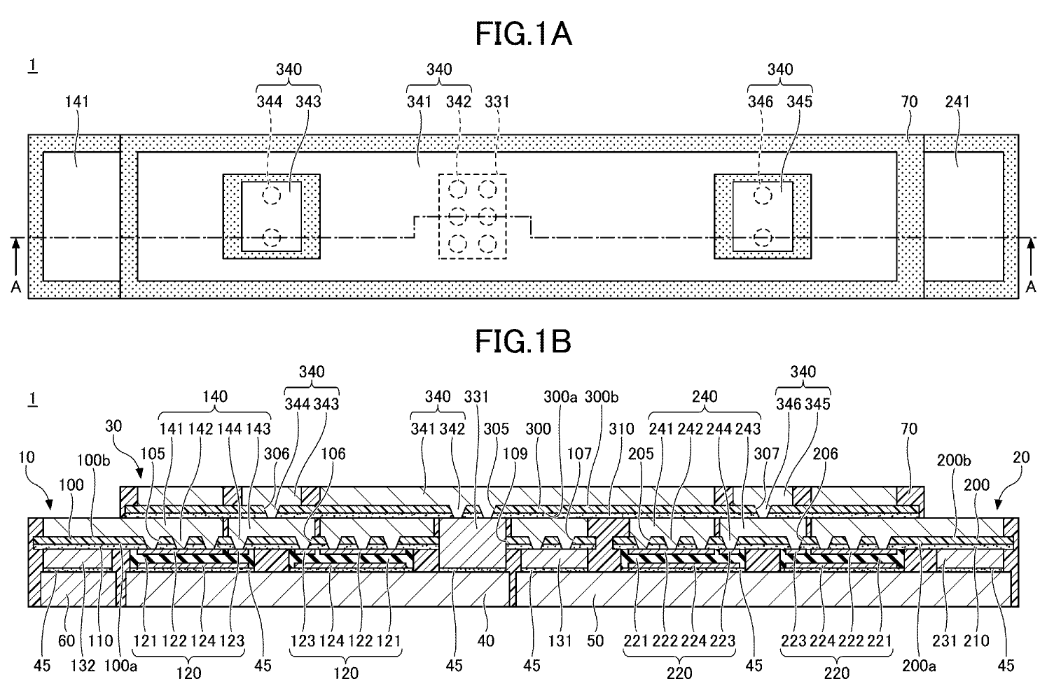

FIGS. 1A and 1B are drawings illustrating an example of a semiconductor apparatus according to a first embodiment. FIG. 1A is a plan view and FIG. 1B is a cross-sectional view taken along line A-A in FIG. 1A. As shown in FIGS. 1A and 1B, a semiconductor apparatus 1 according to the first embodiment includes a first structure 10, a second structure 20 disposed adjacent to the first structure 10, a third structure 30 stacked on the upper side of the first structure 10 and the upper side of the second structure 20, a first interconnect member 40 stacked on the lower side of the first structure 10, and a second interconnect member 50 stacked on the lower side of the second structure 20.

In the first embodiment, for the sake of convenience, the side of the semiconductor apparatus 1 where an interconnect layer 340 is located is referred to as an upper side, and the side where the first interconnect member 40 and the second interconnect member 50 are located is referred to as a lower side. Further, the surface of each portion facing the same direction as the side where the interconnect layer 340 is located is referred to as an upper surface, and the surface facing the same direction as the side where the first interconnect member 40 and the second interconnect member 50 are located is referred to as a lower surface. Nonetheless, the semiconductor apparatus 1 may be positioned upside down when used, or may be arranged at any angle. The plan view refers to the view of an object as seen from the direction normal to the upper surface 300b of a third insulating substrate 300, and the plan shape refers to the shape of an object as seen from the direction normal to the upper surface 300b of the third insulating substrate 300.

The first structure 10 includes a first insulating substrate 100, a first adhesive layer 110, a first semiconductor device 120, conductive members 131 and 132, and an interconnect layer 140. In the illustrated example, the first structure 10 has two first semiconductor devices 120 connected in parallel with each other. When arranged in parallel, the first semiconductor devices 120 may be arranged in a direction parallel to or perpendicular to the longitudinal direction of the semiconductor apparatus 1. The number of first semiconductor devices 120 may be 1, or 3 or more.

The first insulating substrate 100 has a lower surface 100a and an upper surface 100b positioned on the opposite side in the thickness direction from the lower surface 100a. As the first insulating substrate 100, for example, a resin film or the like may be used. The material of the resin film may be an insulating resin such as a polyimide-based resin, a polyethylene-based resin, or an epoxy-based resin. The first insulating substrate 100 possesses, for example, flexibility. Here, the term “flexibility” refers to the ability to be bent or deflected. The first insulating substrate 100 may have any shape and any size. The plan shape of the first insulating substrate 100 is, for example, rectangular. The thickness of the first insulating substrate 100 may be, for example, in the range of approximately 50 μm to 100 μm.

The first adhesive layer 110 is laminated on the lower surface 100a of the first insulating substrate 100. The first adhesive layer 110 may be disposed on the entire lower surface 100a of the first insulating substrate 100, or may be disposed only at necessary portions. The material of the first adhesive layer 110 may be, for example, an epoxy-based adhesive, a polyimide-based adhesive, a silicone-based adhesive, or the like. The thickness of the first adhesive layer 110 may be, for example, in the range of approximately 20 μm to 40 μm.

The first semiconductor device 120 is a device using, for example, silicon (Si) or silicon carbide (SiC). Alternatively, the first semiconductor device 120 may be a device using, for example, gallium nitride (GaN) or gallium arsenide (GaAs). For example, the first semiconductor device 120 may be an active element such as a semiconductor device (for example, a silicon chip such as a CPU), an insulated gate bipolar transistor (IGBT), a metal-oxide-semiconductor field-effect transistor (MOSFET), a diode, or the like. The first semiconductor device 120 of this embodiment is a semiconductor device with electrodes disposed on the front and back surfaces. The first semiconductor device 120 may have any shape and any size. The plan shape of the first semiconductor device 120 may be, for example, rectangular. The thickness of the first semiconductor device 120 may be, for example, in the range of approximately 50 μm to 500 μm.

The first semiconductor device 120 includes a core 121, electrodes 122 and 123 positioned on one side of the core 121 in the thickness direction, and an electrode 124 positioned on the side opposite the electrodes 122 and 123 in the thickness direction. The first semiconductor device 120 is bonded to the lower surface 100a of the first insulating substrate 100 via the first adhesive layer 110 with the electrodes 122 and 123 facing the first insulating substrate 100. The electrode 122, the electrode 123, and the electrode 124 may be, for example, a source electrode, a gate electrode, and a drain electrode, respectively.

The electrode 122, the electrode 123, and the electrode 124 (which may hereinafter be collectively referred to as “electrodes”) may be made of, for example, a metal such as aluminum (Al) or copper (Cu), or an alloy containing at least one metal selected from these metals. According to need, a surface treatment layer may be formed on the surfaces of the electrodes. Examples of the surface treatment layer may include a gold (Au) layer, a nickel (Ni)/Au layer (a metal layer made by laminating a Ni layer and an Au layer in this order), a Ni/palladium (Pd)/Au layer (a metal layer made by laminating a Ni layer, a Pd layer, and an Au layer in this order), and the like. The Au layer, the Ni layer, and the Pd layer may be, for example, a metal layer formed by an electroless plating method (electroless plating metal layer). The Au layer is a metal layer made of Au or an Au alloy, the Ni layer is a metal layer made of Ni or an Ni alloy, and the Pd layer is a metal layer made of Pd or a Pd alloy.

The conductive members 131 and 132 are adhered to the lower surface 100a of the first insulating substrate 100 via the first adhesive layer 110. In the illustrated example, the conductive members 131 and 132 are disposed opposite each other across the two first semiconductor devices 120 in plan view. The conductive members 131 and 132 may be made of, for example, copper or a copper alloy.

The conductive members 131 and 132 may have any shape and any size. The plan shape of each of the conductive members 131 and 132 may be, for example, rectangular. The conductive members 131 and 132 may have the same size or different sizes. The conductive members 131 and 132 have the same thickness. The thicknesses of the conductive members 131 and 132 are equal to the thicknesses of the first semiconductor device 120 and the second semiconductor device 220, and may be, for example, in the range of approximately 50 μm to 500 μm. In the present application, the term “equal thickness” permits a thickness difference of up to 10 μm between the compared objects.

The interconnect layer 140 includes an interconnect 141, via interconnects 142 formed seamlessly with the interconnect 141, an interconnect 143, and via interconnects 144 formed seamlessly with the interconnect 143. The interconnects 141 and 143 are disposed on the upper surface 100b of the first insulating substrate 100. The thicknesses of the interconnects 141 and 143 may be, for example, in the range of approximately 50 μm to 150 μm.

The via interconnects 142 are disposed in through holes 105 that penetrate the first insulating substrate 100 and the first adhesive layer 110 to reach the upper surfaces of the electrodes 122 of the first semiconductor devices 120. The via interconnects 142 are disposed in through holes 107 that penetrate the first insulating substrate 100 and the first adhesive layer 110 to reach the upper surface of the conductive member 131. The via interconnects 144 are disposed in through holes 106 that penetrate the first insulating substrate 100 and the first adhesive layer 110 to reach the electrodes 123 of the first semiconductor devices 120. In the illustrated example, the quantity of each of the through holes 105 to 107 is at least two. The quantity of each of the through holes 105 to 107 may be any number of 1 or more.

The interconnect 141 is electrically connected to the electrodes 122 of the first semiconductor devices 120 via the via interconnects 142. The interconnect 141 is also electrically connected to the conductive member 131 via the via interconnects 142. The interconnect 143 is electrically connected to the electrodes 123 of the first semiconductor devices 120 via the via interconnects 144. The conductive member 132 need not be electrically connected to the interconnects 141 and 143. In this case, the conductive member 132 functions as a spacer or a supporting member.

The interconnect layer 140 may have a structure made by laminating a metal layer on a seed layer, for example. In this case, a metal film (sputtered film) formed by a sputtering method, for example, may be used as the seed layer. As the seed layer formed by the sputtering method, a metal film having a 2-layer structure made by sequentially laminating a titanium layer and a copper layer, for example, may be used. In such a case, the thickness of the Ti layer may be, for example, in the range of approximately 10 nm to 300 nm, and the thickness of the Cu layer may be, for example, in the range of approximately 100 nm to 1000 nm. The Ti layer functions as an adhesion layer for improving adhesion between the seed layer and each of the first insulating substrate 100, the electrodes, etc. The Ti layer also functions as a metal barrier layer for suppressing diffusion of copper from the Cu layer and the like to the first insulating substrate 100 and the like. As the material of the metal film functioning as the adhesion layer and the metal barrier layer, titanium nitride (TiN), tantalum nitride (TaN), tantalum (Ta), chromium (Cr), or the like may be used in place of Ti. The material of the metal layer may be, for example, copper or a copper alloy. As the metal layer, for example, a metal layer formed by an electrolytic plating method (electrolytic plating metal layer) may be used.

The second structure 20 includes a second insulating substrate 200, a second adhesive layer 210, a second semiconductor device 220, a conductive member 231, and an interconnect layer 240. The overall thickness of the second structure 20 may be equal to the overall thickness of the first structure 10, for example.

In the illustrated example, the second structure 20 has two second semiconductor devices 220 connected in parallel with each other. When disposed in parallel, the second semiconductor devices 220 may be arranged in a direction parallel to or perpendicular to the longitudinal direction of the semiconductor apparatus 1. The number of second semiconductor devices 220 may be 1, or 3 or more.

The second insulating substrate 200 has a lower surface 200a and an upper surface 200b positioned on the opposite side in the thickness direction from the lower surface 200a. The material and thickness of the second insulating substrate 200 may be, for example, substantially the same as those of the first insulating substrate 100.

The second adhesive layer 210 is laminated on the lower surface 200a of the second insulating substrate 200. The second adhesive layer 210 may be disposed on the entire lower surface 200a of the second insulating substrate 200, or may be disposed only at necessary positions. The material and thickness of the second adhesive layer 210 may be, for example, substantially the same as those of the first adhesive layer 110.

The second semiconductor device 220 is a device similar to the first semiconductor device 120. The second semiconductor device 220 may be connected in series with the first semiconductor device 120, for example. The material and thickness of the second semiconductor device 220 may be substantially the same as those of the first semiconductor device 120. The second semiconductor device 220 may have any shape and any size. The plan shape of the second semiconductor device 220 may be rectangular, for example. The plan shape of the second semiconductor device 220 may be substantially the same as that of the first semiconductor device 120, for example.

The second semiconductor device 220 includes a core 221, electrodes 222 and 223 positioned on one side of the core 221 in the thickness direction, and an electrode 224 positioned on the side opposite the electrodes 222 and 223 in the thickness direction. The second semiconductor device 220 is bonded to the lower surface 200a of the second insulating substrate 200 via the second adhesive layer 210 with the electrodes 222 and 223 facing the second insulating substrate 200. The electrodes 222, 223, and 224 may be, for example, a source electrode, a gate electrode, and a drain electrode, respectively. The materials and surface treatment of the electrodes 222, 223, and 224 may be substantially the same as those of the electrodes 122, 123, and 124, for example.

The conductive member 231 may be made of, for example, copper, a copper alloy, or the like. The conductive member 231 may have any shape and any size. The plan shape of the conductive member 231 may be, for example, rectangular. The thickness of the conductive member 231 is equal to the thickness of the second semiconductor device 220 and may be, for example, in the range of approximately 50 μm to 500 μm. The conductive member 231 may not be electrically connected to the interconnects 241 and 243. In this case, the conductive member 231 functions as a spacer or a support member.

The interconnect layer 240 includes an interconnect 241, via interconnects 242 formed seamlessly with the interconnect 241, an interconnect 243, and via interconnects 244 formed seamlessly with the interconnect 243. The interconnects 241 and 243 are disposed on the upper surface 200b of the second insulating substrate 200. The thickness of each of the interconnects 241 and 243 is equal to the thickness of each of the interconnects 141 and 143, and may be, for example, in the range of approximately 50 μm to 150 μm.

The via interconnects 242 are disposed in through holes 205 that penetrate the second insulating substrate 200 and the second adhesive layer 210 to reach the electrodes 222 of the second semiconductor devices 220. The via interconnects 244 are disposed in the through holes 206 that penetrate the second insulating substrate 200 and the second adhesive layer 210 to reach the electrodes 223 of the second semiconductor device 220. In the illustrated example, the quantity of each of the through holes 205 and 206 is at least two. The quantity of each of the through holes 205 and 206 may be any number of 1 or more.

The interconnect 241 is electrically connected to the electrodes 222 of the second semiconductor devices 220 via the via interconnects 242. The interconnect 243 is electrically connected to the electrodes 223 of the second semiconductor devices 220 via the via interconnects 244. The interconnect layer 240 may have a structure made by laminating a metal layer on a seed layer, for example, in substantially the same manner as the interconnect layer 140.

The third structure 30 includes a third insulating substrate 300, a third adhesive layer 310, a conductive member 331, and an interconnect layer 340.

The third insulating substrate 300 has a lower surface 300a and an upper surface 300b positioned on the opposite side in the thickness direction from the lower surface 300a. The material and the thickness of the third insulating substrate 300 may be substantially the same as those of the first insulating substrate 100, for example.

The third adhesive layer 310 is laminated on the lower surface 300a of the third insulating substrate 300. The lower surface of the third insulating substrate 300 is bonded to the upper surfaces of the interconnects 141 and 143 and the upper surfaces of the interconnects 241 and 243 via the third adhesive layer 310. The third adhesive layer 310 may be disposed on the entire lower surface 300aof the third insulating substrate 300, or may be disposed only at necessary positions. The material and thickness of the third adhesive layer 310 may be, for example, substantially the same as those of the first adhesive layer 110.

The conductive member 331 may be made of, for example, copper, a copper alloy, or the like. The conductive member 331 may have any shape and any size. The plan shape of the conductive member 331 may be, for example, rectangular. The thickness of the conductive member 331 may be, for example, equal to the overall thickness of the first structure 10 and the overall thickness of the second structure 20.

The interconnect layer 340 includes an interconnect 341, via interconnects 342 formed seamlessly with the interconnect 341, an interconnect 343, via interconnects 344 formed seamlessly with the interconnect 343, an interconnect 345, and via interconnects 346 formed seamlessly with the interconnect 345. The interconnects 341, 343, and 345 are disposed on the upper surface 300b of the third insulating substrate 300. The thicknesses of the interconnects 341, 343, and 345 are equal to the thicknesses of the interconnects 141 and 143, and may be, for example, in the range of approximately 50 μm to 150 μm.

The via interconnects 342 are disposed in through holes 305 that penetrate the third insulating substrate 300 and the third adhesive layer 310 to reach the upper surface of the conductive member 331. The via interconnects 344 are disposed in through holes 306 that penetrate the third insulating substrate 300 and the third adhesive layer 310 to reach the upper surface of the interconnect 143. The via interconnects 346 are disposed in through holes 307 that penetrate the third insulating substrate 300 and the third adhesive layer 310 to reach the upper surface of the interconnect 243. In the illustrated example, the quantity of each of the through holes 305 to 307 is at least two. The quantity of each of the through holes 305 to 307 may be any number of 1 or more.

The interconnect 341 is electrically connected to the conductive member 331 via the via interconnects 342. The interconnect 343 is electrically connected to the interconnect 143 via the via interconnects 344. The interconnect 345 is electrically connected to the interconnect 243 via the via interconnects 346. The interconnect layer 340 may have a structure made by laminating a metal layer on a seed layer, for example, in substantially the same manner as the interconnect layer 140.

The first interconnect member 40 is electrically connected to the electrodes 124 of the first semiconductor devices 120 and the conductive member 331 via the conductive adhesive layer 45. The first interconnect member 40 is a part of the path that electrically connects the electrodes 124 and the interconnect 341. In the illustrated example, the first interconnect member 40 has a region capable of vertical electrical connection with the third structure 30, and the conductive member 331 is arranged on this region. The lower surface of the conductive member 331 is electrically connected to the first interconnect member 40 via the conductive adhesive layer 45, and the upper surface of the conductive member 331 is electrically connected to the interconnect 341 via the via interconnects 342 penetrating the third insulating substrate 300 and the third adhesive layer 310.

In the illustrated example, the first structure 10 has a through hole 109 penetrating the first insulating substrate 100 and the first adhesive layer 110, and the through hole 109 is aligned in plan view with the region where the first interconnect member 40 and the third structure 30 are electrically connectable in the vertical direction to each other. The conductive member 331 is located in the through hole 109 in plan view. The conductive member 331 may be disposed, for example, between the first semiconductor device 120 and the second semiconductor device 220 adjacent to each other. The conductive member 331 may or may not be in contact with the first insulating substrate 100 and the first adhesive layer 110.

Using the conductive member 331 having the same thickness as the first structure 10 and the second structure 20 as described above effectively facilitates connection between the first interconnect member 40 and the interconnect 341, as compared to the use of a stacked via structure. That is, it is difficult to manufacture a stacked via structure by filling large-diameter via holes, intended for carrying a large current, with copper or the like, so that employing the conductive member 331, which eliminates such a difficulty, is advantageous.

The second interconnect member 50 is electrically connected to the electrodes 224 of the second semiconductor devices 220, the conductive member 131, and the conductive member 231 via the conductive adhesive layer 45. The second interconnect member 50 is a part of the path that electrically connects the electrodes 224 to the interconnect 141. In the illustrated example, the second interconnect member 50 has a region facing the first structure 10, and the conductive member 131 is disposed in this region. The lower surface of the conductive member 131 is electrically connected to the second interconnect member 50 via the conductive adhesive layer 45, and the upper surface of the conductive member 131 is electrically connected to the interconnect 141 via the via interconnects 142 penetrating the first insulating substrate 100 and the first adhesive layer 110. The conductive member 131 may be disposed, for example, between the first semiconductor device 120 and the second semiconductor device 220 adjacent to each other. The first interconnect member 40 and the second interconnect member 50 may be made of, for example, copper, a copper alloy, or the like. Alternatively, the first interconnect member 40 and the second interconnect member 50 may each be a member of an interconnect substrate such as a ceramic substrate.

The conductive member 60 is electrically connected to the conductive member 132 via the conductive adhesive layer 45. The conductive member 60 may be made of, for example, copper, a copper alloy, or the like. The conductive adhesive layer 45 is, for example, a solder layer or a sintered metal layer. The conductive adhesive layer 45 may be made of a conductive paste such as silver paste.

A sealant resin 70 is formed so as to leave exposed the entire upper surfaces of the interconnects 341, 343, and 345, portions of the upper surfaces of the interconnects 141 and 241, and the entire lower surfaces of the first interconnect member 40, the second interconnect member 50, and the conductive member 60, and to cover the remaining portions. The sealant resin 70 may be, for example, an insulating resin such as a thermosetting epoxy-based resin containing a filler. In FIG. 1A, the sealant resin 70 is illustrated in a dot pattern for convenience.

As described above, the semiconductor apparatus 1 includes the first structure 10 including the first semiconductor device 120, the second structure 20 including the second semiconductor device 220, and the third structure 30. The second structure 20 is located alongside the first structure 10, and the third structure 30 is stacked on the upper side of the first structure 10 and the upper side of the second structure 20. The first interconnect member 40 is stacked on the lower side of the first structure 10, and the second interconnect member 50 is stacked on the lower side of the second structure 20. The first interconnect member 40 is a part of the path that electrically connects the electrode 124 of the first semiconductor device 120 and the interconnect 341, and the second interconnect member 50 is a part of the path that electrically connects the electrode 224 and the interconnect 141.

In the semiconductor apparatus 1, the first structure 10, the second structure 20, and the third structure 30 have the same basic structure. That is, in each of the structures, an adhesive layer is provided on the lower surface of an insulating substrate, a semiconductor device and/or a conductive member are disposed on the lower surface of the insulating substrate via the adhesive layer, and an interconnect layer is disposed on the upper surface of the insulating substrate to be electrically connected to the semiconductor device and/or the conductive member by extending through the insulating substrate and the adhesive layer. By placing the structures having the same basic structure side by side and in a stacked manner, the manufacture of the semiconductor apparatus 1 having a multilayer structure capable of easily connecting semiconductor devices is effectively achieved. In addition, such a structure facilitates size reduction of the semiconductor apparatus 1.

Although it is possible to combine the first structure 10 and the second structure 20 into one structure, the degree of design freedom is improved by providing two separate structures. Further, providing two separate structures enables the screening of non-defective products on a structure-by-structure basis at the time of manufacturing the structures, which results in a yield improvement. Moreover, it is also easy to arrange the structures into a three or more multiphase configuration (for example, a three-phase configuration used in inverters).

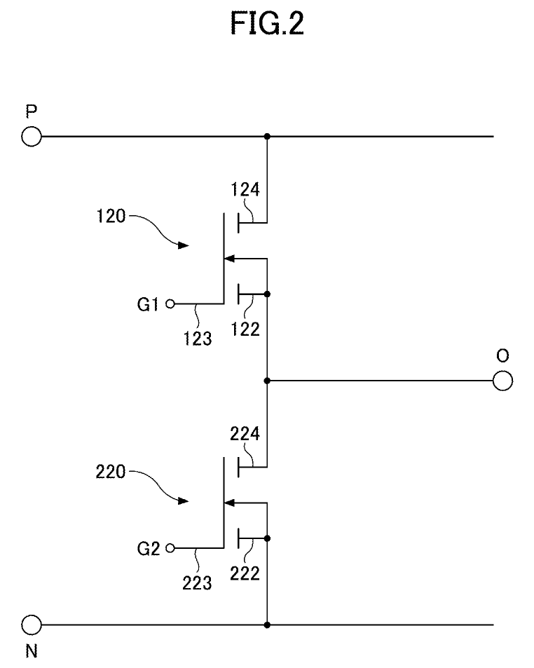

The following now describes an example of a circuit configuration of the semiconductor apparatus 1 according to the first embodiment. FIG. 2 is a drawing illustrating an example of a basic circuit of the semiconductor apparatus according to the first embodiment. FIG. 2 illustrates one first semiconductor device 120 and one second semiconductor device 220, while in FIG. 1, the two first semiconductor devices 120 are connected in parallel, and the two second semiconductor devices 220 are connected in parallel. In FIG. 2, a protection diode may be connected in parallel to each of the first semiconductor device 120 and the second semiconductor device 220.

As illustrated in FIG. 2, the first semiconductor device 120 and the second semiconductor device 220 may be connected in series. Specifically, for the first semiconductor device 120, the electrode 124 is electrically connected to the P terminal, and the electrode 123 is electrically connected to the G1 terminal. For the second semiconductor device 220, the electrode 222 is electrically connected to the N terminal, and the electrode 223 is electrically connected to the G2 terminal. The electrode 122 of the first semiconductor device 120 and the electrode 224 of the second semiconductor device 220 are electrically connected to the O terminal. The P terminal is an input terminal on the positive side, the N terminal is an input terminal on the negative side, and the O terminal is an output terminal. The G1 terminal and the G2 terminal are control terminals. The circuit illustrated in FIG. 2 enables high-speed switching operation based on the first semiconductor device 120 and the second semiconductor device 220.

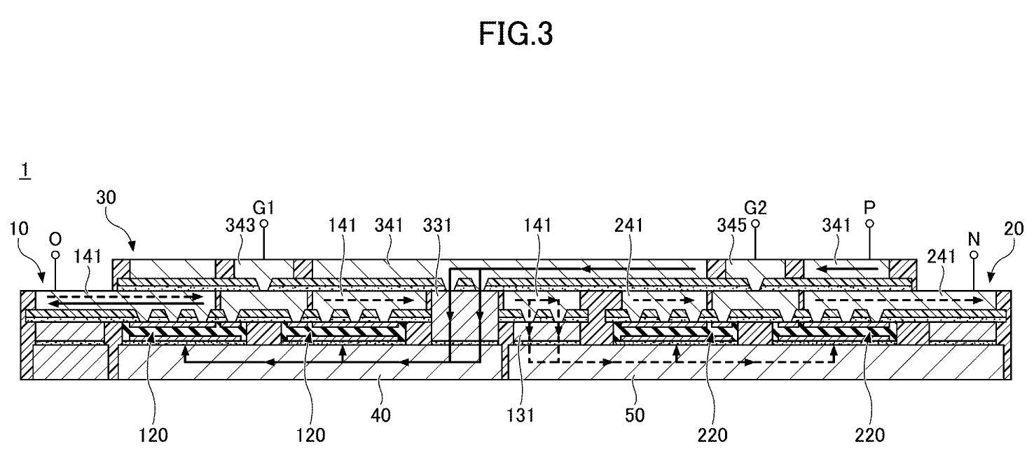

FIG. 3 is a drawing illustrating a current flow in the semiconductor apparatus according to the first embodiment. In FIG. 3, the P terminal, N terminal, the O terminal, the G1 terminal, and the G2 terminal correspond to those illustrated in the circuit diagram of FIG. 2. The solid arrows in FIG. 3 schematically represent the path of the current flowing from the P terminal to the O terminal. The dashed arrows schematically represent the path of the current flowing from the O terminal to the N terminal.

As illustrated in FIG. 3, the semiconductor apparatus 1 is configured such that while the current flows from the P terminal to the N terminal, the directions of current flow are opposite between the first interconnect member 40 and the interconnect 141, and the directions of current flow are opposite between the interconnect 341 and each of the second interconnect member 50 and the interconnect 241. That is, the P-side current path from the P terminal to the O terminal and the N-side current path from the O terminal to the N terminal are arranged substantially vertically adjacent to each other, and carry currents in opposite directions, which effectively reduces the inductance. In the semiconductor apparatus 1, the spacing between the P-side current path and the N-side current path in the thickness direction is as small as a few hundred micrometers, thereby exhibiting a significant reduction in inductance.

### Method of Making Semiconductor Apparatus

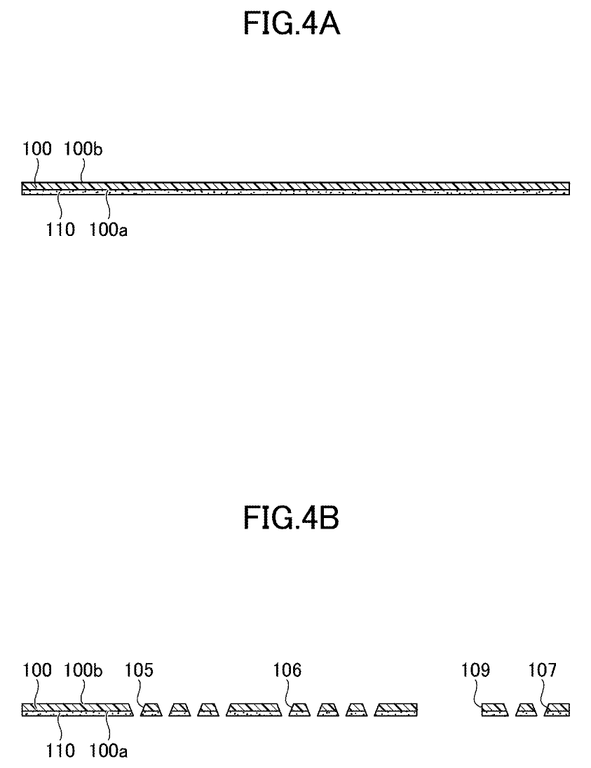

The following describes a method of making the semiconductor apparatus according to the first embodiment. FIGS. 4A and 4B to FIGS. 11A and 11B are drawings illustrating an example of a manufacturing process of the semiconductor apparatus according to the first embodiment. The following description is directed to an example of manufacturing one semiconductor apparatus. However, a multi-piece manufacturing method may alternatively be employed, in which sections intended for semiconductor devices 1 are collectively fabricated, followed by singulation to produce individual semiconductor apparatuses 1. For convenience of description, the portions to be the final components of the semiconductor apparatus 1 will be referred to by respective reference numerals of the final components.

First, as illustrated in FIG. 4A, a first insulating substrate 100 having a lower surface 100a and an upper surface 100b and a first adhesive layer 110 are prepared. The insulating first adhesive layer 110 covering the entire lower surface 100a is provided on the lower surface 100a of the first insulating substrate 100.

As illustrated in FIG. 4B, through holes 105 to 107 and 109 penetrating the first insulating substrate 100 and the first adhesive layer 110 in the thickness direction are formed at intended locations on the first insulating substrate 100 and the first adhesive layer 110. The through holes 105 to 107 and 109 may be formed by, for example, laser processing with a CO₂ laser, a UV-YAG laser, or the like, or by punching. The through holes 105 are formed at positions where the electrode 122 of the first semiconductor device 120 is exposed in a subsequent step. The through holes 106 are formed at positions where the electrode 123 of the first semiconductor device 120 is exposed in a subsequent step. The through holes 107 are formed at positions where the upper surface of the conductive member 131 is exposed in a subsequent step. The through hole 109 is formed at a position where the conductive member 331 may be disposed in a subsequent process. The quantity of each of the through holes 105 to 107 may be any number that is at least one.

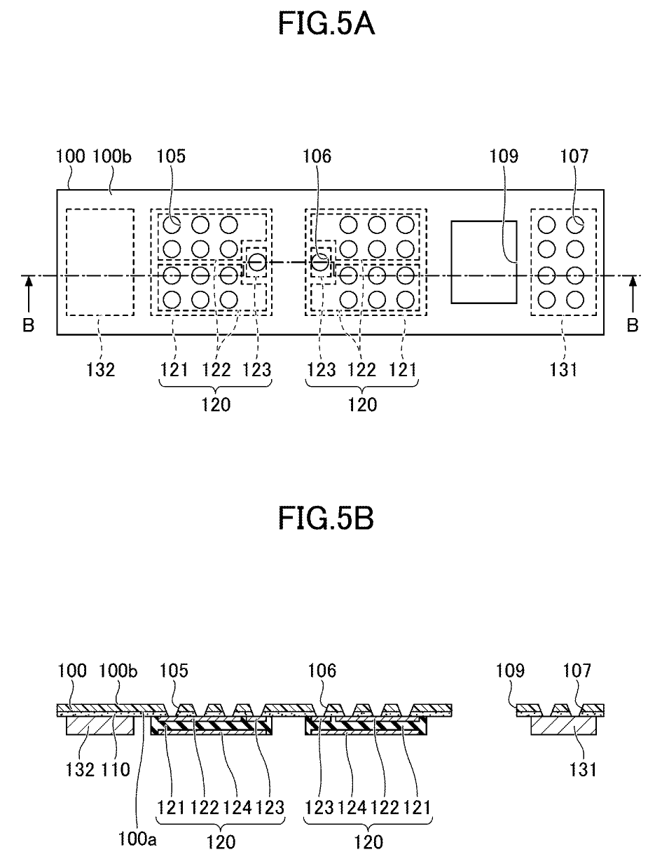

As illustrated in FIGS. 5A and 5B, first semiconductor devices 120 and a conductive member 131 are bonded to the first insulating substrate 100 by the first adhesive layer 110. At this time, the sides of the first semiconductor devices 120 with the electrodes 122 and 123 are made to face the lower surface 100a of the first insulating substrate 100, and alignment is performed so that the electrodes 122 overlap the through holes 105 and the electrodes 123 overlap the through holes 106 in plan view. Further, alignment is performed so that the upper surface of the conductive member 131 overlaps the through holes 107 in plan view. FIG. 5A is a plan view, and FIG. 5B is a cross-sectional view taken along line B-B in FIG. 5A.

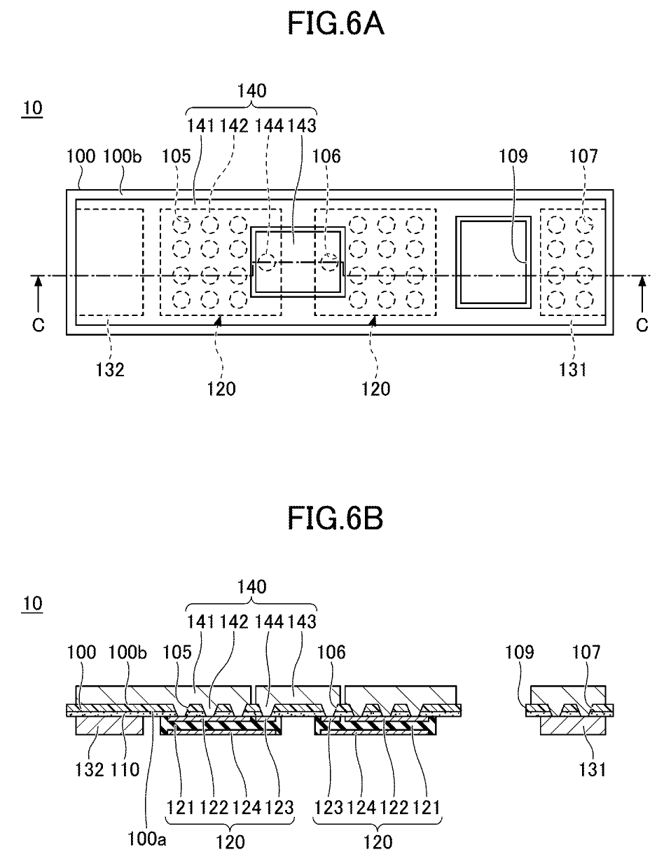

As illustrated in FIGS. 6A and 6B, an interconnect layer 140 is formed. The interconnect layer 140 includes an interconnect 141, via interconnects 142 formed seamlessly with the interconnect 141, an interconnect 143, and via interconnects 144 formed seamlessly with the interconnect 143. The interconnects 141 and 143 are disposed on the upper surface 100b of the first insulating substrate 100. The via interconnects 142 are disposed in the through holes 105 that penetrate the first insulating substrate 100 and the first adhesive layer 110 to expose the electrodes 122 of the first semiconductor devices 120, and are disposed in the through holes 107 that penetrate the first insulating substrate 100 and the first adhesive layer 110 to expose the upper surface of the conductive member 131. The via interconnects 144 are disposed in the through holes 106 that penetrate the first insulating substrate 100 and the first adhesive layer 110 to expose the electrodes 123 of the first semiconductor devices 120.

The interconnect layer 140 may be formed, for example, by a semi-additive method. Specifically, a seed layer is formed so as to cover the entire upper surface 100b of the first insulating substrate 100 and the entire inner surfaces of the through holes 105 to 107. The seed layer may be formed, for example, by a sputtering method or an electroless plating method. For example, when the seed layer is formed by a sputtering method, first, titanium is deposited by sputtering so as to cover the upper surface 100b of the first insulating substrate 100 and the inner surfaces of the through holes 105 to 107, thereby forming a Ti layer. Then, copper is deposited by sputtering on the Ti layer to form a Cu layer. This effectively forms a seed layer having a 2-layer structure (Ti layer/Cu layer). When the seed layer is formed by electroless plating, for example, a seed layer composed of a Cu layer (1-layer structure) may be formed by electroless copper plating.

Subsequently, a plating resist layer is formed on the seed layer, with openings at areas where the interconnect layer 140 is formed, i.e., areas where the interconnects 141 and 143 are formed. A metal layer composed of copper or the like is then formed in the openings of the plating resist layer by electroplating using the seed layer as a current supply path for plating. The plating resist layer is thereafter removed. Subsequently, the seed layer is removed by wet etching using the metal layer as a mask. By this procedure, the interconnect layer 140 including the seed layer and the metal layer is effectively formed. The first insulating substrate 100, the first adhesive layer 110, and the interconnect layer 140 may constitute, for example, a flexible interconnect substrate. FIG. 6A is a plan view, and FIG. 6B is a cross-sectional view taken along line C-C in FIG. 6A. By following the steps of FIGS. 4A and 4B to FIGS. 6A and 6B, the manufacture of the first structure 10 is completed.

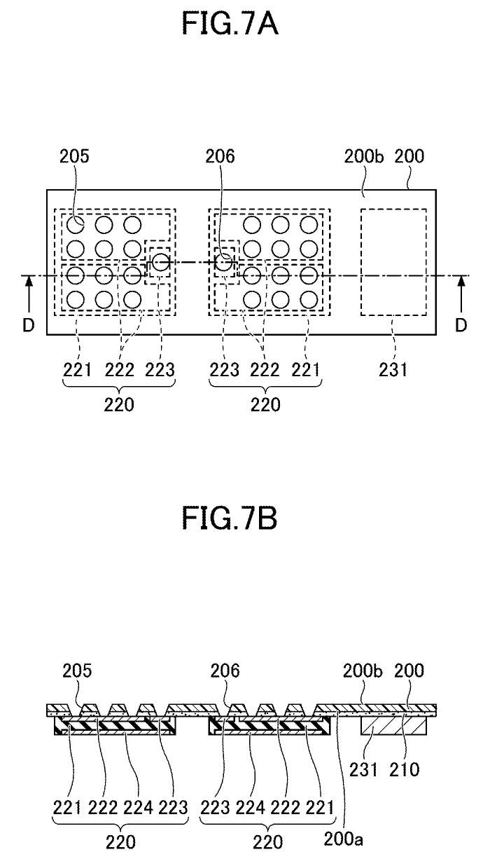

A second structure 20 is manufactured in substantially the same manner as the first structure 10. First, as illustrated in FIGS. 7A and 7B, a second insulating substrate 200 having a lower surface 200a and an upper surface 200b and a second adhesive layer 210 are prepared in substantially the same manner as FIG. 4A. The insulating second adhesive layer 210 covering the entire lower surface 200a is provided on the lower surface 200a of the second insulating substrate 200. In substantially the same manner as illustrated in FIG. 4B, through holes 205 and 206 penetrating the second insulating substrate 200 and the second adhesive layer 210 in the thickness direction are formed at intended locations on the second insulating substrate 200 and the second adhesive layer 210. The through holes 205 are formed at positions where the electrodes 222 of the second semiconductor devices 220 are to be exposed, and the through holes 206 are formed at positions where the electrodes 223 of the second semiconductor devices 220 are to be exposed. The quantity of each of the through holes 205 and 206 may be any number that is at least one.

Further, in substantially the same manner as in FIGS. 5A and 5B, second semiconductor devices 220 and a conductive member 231 are bonded to the second insulating substrate 200 by the second adhesive layer 210. At this time, the sides of the second semiconductor devices 220 with the electrodes 222 and 223 are made to face the lower surface 200a of the second insulating substrate 200, and alignment is performed so that the electrodes 222 overlap the through holes 205 and the electrodes 223 overlap the through holes 206 in plan view. FIG. 7A is a plan view, and FIG. 7B is a cross-sectional view taken along line D-D in FIG. 7A.

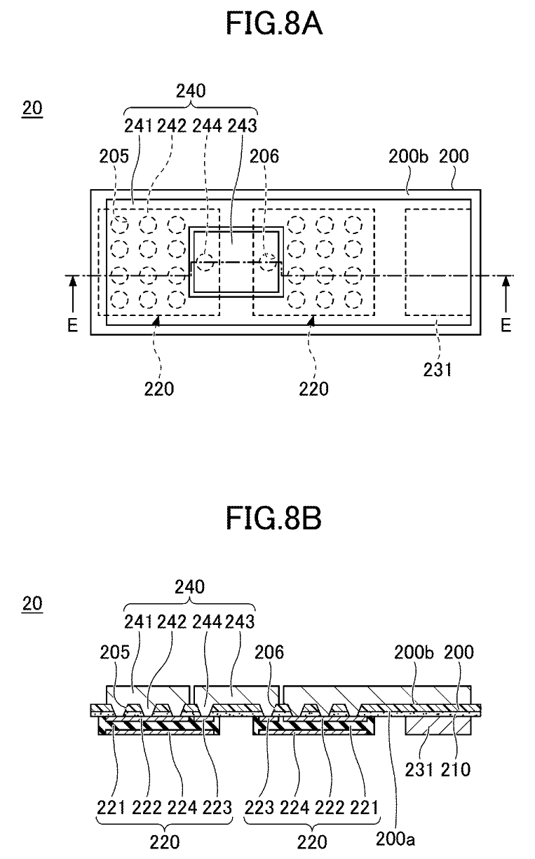

As illustrated in FIGS. 8A and 8B, an interconnect layer 240 is formed in the substantially same manner as in FIGS. 6A and 6B. The interconnect layer 240 includes an interconnect 241, via interconnects 242 formed seamlessly with the interconnect 241, an interconnect 243, and via interconnects 244 formed seamlessly with the interconnect 243. The interconnects 241 and 243 are disposed on the upper surface 200b of the second insulating substrate 200. The via interconnects 242 are disposed in through holes 205 that penetrate the second insulating substrate 200 and the second adhesive layer 210 to expose the electrodes 222 of the second semiconductor devices 220. The via interconnects 244 are disposed in through holes 206 that penetrate the second insulating substrate 200 and the second adhesive layer 210 to expose the electrodes 223 of the second semiconductor devices 220. The interconnect layer 240 may be formed, for example, by a semi-additive method. FIG. 8A is a plan view, and FIG. 8B is a cross-sectional view taken along line E-E in FIG. 8A. By following the steps of FIGS. 7A and 7B and FIGS. 8A and 8B, the fabrication of the second structure 20 is completed.

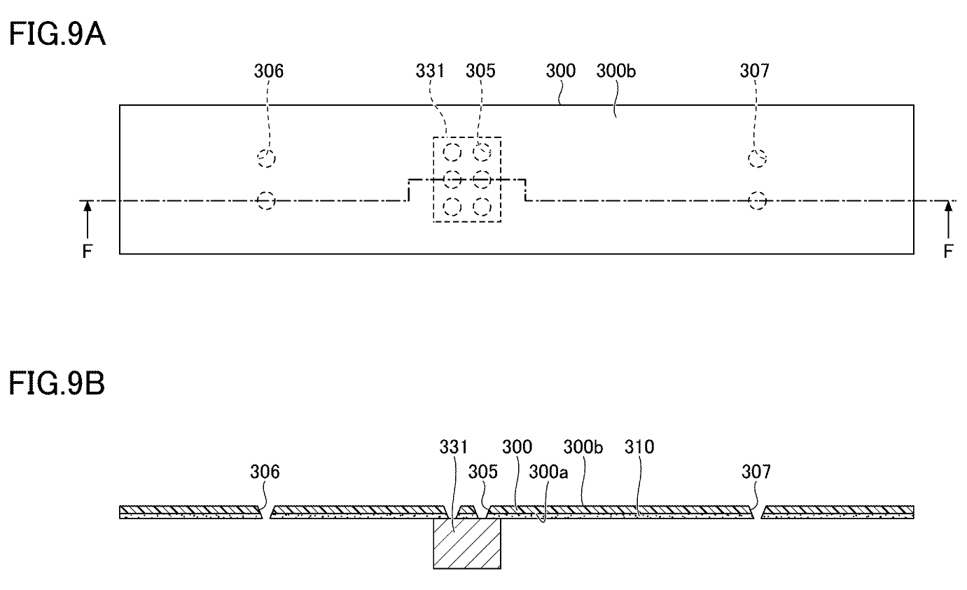

A third structure 30 is manufactured in substantially the same manner as the first structure 10. First, as illustrated in FIGS. 9A and 9B, a third insulating substrate 300 having a lower surface 300a and an upper surface 300b and a third adhesive layer 310 are prepared in substantially the same manner as in FIG. 4A. The insulating third adhesive layer 310 covering the entire lower surface 300a is provided on the lower surface 300a of the third insulating substrate 300. In substantially the same manner as illustrated in FIG. 4B, through holes 305 to 307 penetrating the third insulating substrate 300 and the third adhesive layer 310 in the thickness direction are formed at intended locations on the third insulating substrate 300 and the third adhesive layer 310. The through holes 305 are formed at positions where the upper surface of the conductive member 331 is to be exposed. The through holes 306 are formed at positions where the upper surface of the interconnect 143 is to be exposed in a subsequent step. The through holes 307 are formed at positions where the upper surface of the interconnect 243 is to be exposed in a subsequent step. The quantity of each of the through holes 305 to 307 may be any number that is at least one.

Further, in substantially the same manner as in FIGS. 5A and 5B, a conductive member 331 is bonded to the third insulating substrate 300 by the third adhesive layer 310. At this time, alignment is performed so that the upper surface of the conductive member 331 overlaps the through holes 305 in plan view. FIG. 9A is a plan view, and FIG. 9B is a cross-sectional view taken along line F-F in FIG. 9A.

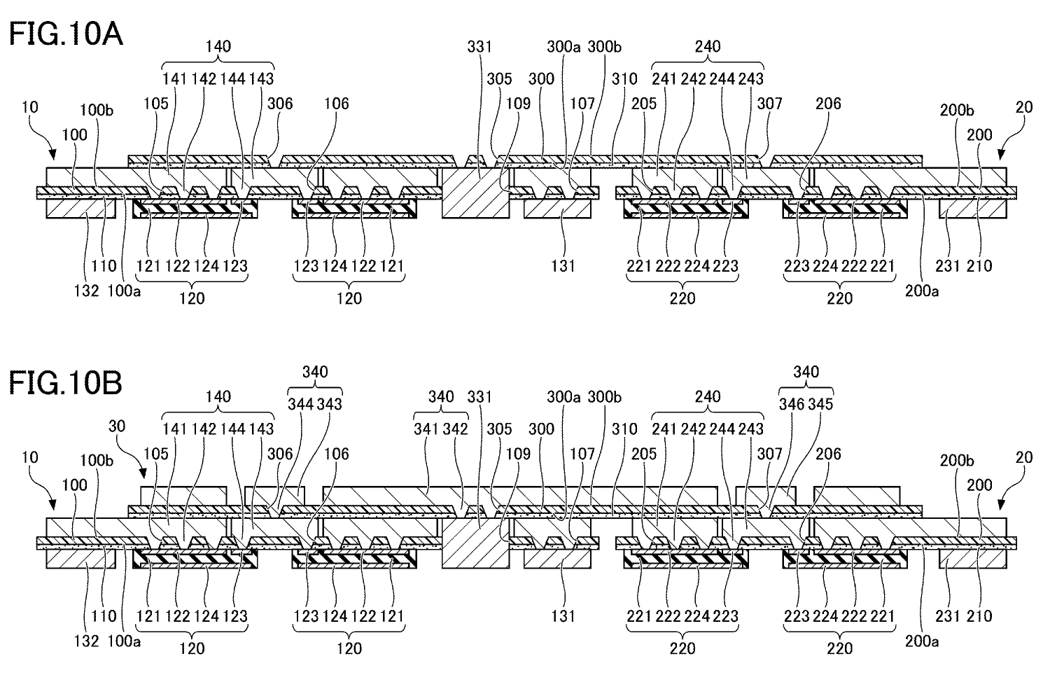

As illustrated in FIG. 10A, the second structure 20 is disposed alongside the first structure 10. For example, the first structure 10 and the second structure 20 are disposed such that, in plan view, the two first semiconductor devices 120 and the two second semiconductor devices 220 are all aligned along a straight line in the longitudinal direction. Then, the structure prepared in FIGS. 9A and 9B is stacked on the upper side of the first structure 10 and the upper side of the second structure 20 such that the third adhesive layer 310 faces the first structure 10 and the second structure 20 and the conductive member 331 is inserted into the through hole 109. The third insulating substrate 300 is bonded to the interconnect layers 140 and 240 via the third adhesive layer 310. The upper surfaces of the interconnects 141 and 143 and the upper surfaces of the interconnects 241 and 243 are flush with each other, for example.

As illustrated in FIG. 10B, an interconnect layer 340 is formed in substantially the same manner as in FIGS. 6A and 6B. The interconnect layer 340 includes an interconnect 341, via interconnects 342 formed seamlessly with the interconnect 341, an interconnect 343, via interconnects 344 formed seamlessly with the interconnect 343, an interconnect 345, and via interconnects 346 formed seamlessly with the interconnect 345. The interconnect 341, 343, and 345 are disposed on the upper surface 300b of the third insulating substrate 300. The via interconnects 342 are disposed in the through holes 305, which penetrate the third insulating substrate 300 and the third adhesive layer 310 to expose the upper surface of the conductive member 331. The via interconnects 344 are disposed in the through holes 306, which penetrate the third insulating substrate 300 and the third adhesive layer 310 to expose the upper surface of the interconnect 143. The via interconnects 346 are disposed in the through holes 307, which penetrate the third insulating substrate 300 and the third adhesive layer 310 to expose the upper surface of the interconnect 243. The interconnect layer 340 may be formed, for example, by a semi-additive method. These steps achieve the fabrication of a structure in which the third structure 30 is stacked on the upper side of the first structure 10 and the upper side of the second structure 20.

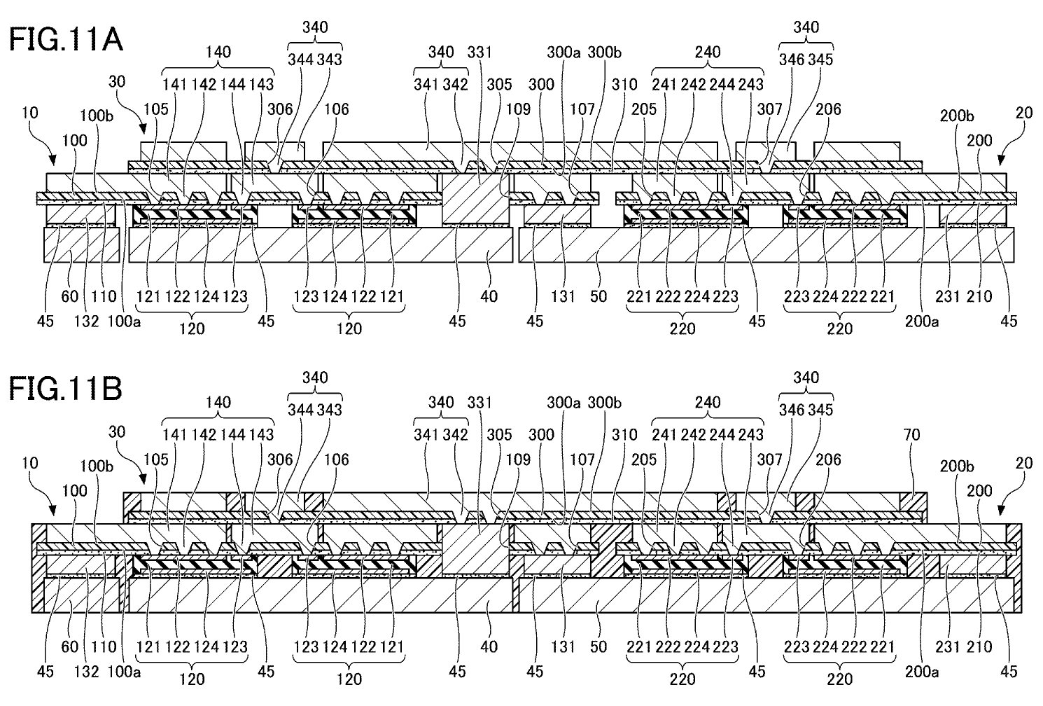

Next, in the step illustrated in FIG. 11A, a first interconnect member 40 is bonded to the conductive member 331 and the electrodes 124 of the first semiconductor devices 120 by a conductive adhesive layer 45. Further, a second interconnect member 50 is bonded to the conductive members 131 and 231 and the electrodes 224 of the second semiconductor devices 220 by the conductive adhesive layer 45. A conductive member 60 is also bonded to the conductive member 132 by the conductive adhesive layer 45.

In the step illustrated in FIG. 11B, a sealant resin 70 is formed. The sealant resin 70 is formed so as to leave exposed the entire upper surfaces of the interconnects 341, 343, and 345, portions of the upper surfaces of the interconnects 141 and 241, and the entire lower surfaces of the first interconnect member 40, the second interconnect member 50, and the conductive member 60, and to cover the remaining portions. The sealant resin 70 may be, for example, an insulating resin such as a thermosetting epoxy-based resin containing a filler. The sealant resin 70 may be formed, for example, by a transfer molding method using a sealant mold. The shape of the sealant resin 70 as illustrated in FIG. 11B is effectively achieved by adjusting the shape of the sealant mold.

Through the process described above, the manufacture of the semiconductor apparatus 1 is effectively achieved. In the manufacturing process of the semiconductor apparatus 1, the basic structures of the first structure 10, the second structure 20, and the third structure 30 are the same, and all the structures are arranged so that the positional relationship between the insulating substrate and the adhesive layer in the vertical direction is the same. That is, the process does not include a step of inverting any of the structures for connection or bending any of the structures. No complicated steps are thus involved, thereby effectively achieving a simple manufacturing process.

According to at least one embodiment, a semiconductor apparatus is provided that has a multilayer structure capable of easily connecting semiconductor devices to one another.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor apparatus comprising:
a first structure;
a second structure disposed alongside the first structure;
a third structure stacked on an upper side of the first structure and an upper side of the second structure;
a first interconnect member stacked on a lower side of the first structure; and
a second interconnect member stacked on a lower side of the second structure,
wherein the first structure includes:
a first insulating substrate;
a first semiconductor device having a first electrode and a second electrode disposed opposite the first electrode in a thickness direction, the first semiconductor device being bonded to a lower surface of the first insulating substrate via a first adhesive layer with the first electrode facing the first insulating substrate; and
a first interconnect disposed on an upper surface of the first insulating substrate and electrically connected to the first electrode via a first via interconnect penetrating the first insulating substrate and the first adhesive layer,
wherein the second structure includes:
a second insulating substrate;
a second semiconductor device having a third electrode and a fourth electrode disposed opposite the third electrode in a thickness direction, the second semiconductor device being bonded to a lower surface of the second insulating substrate via a second adhesive layer with the third electrode facing the second insulating substrate; and
a second interconnect disposed on an upper surface of the second insulating substrate and electrically connected to the third electrode via a second via interconnect penetrating the second insulating substrate and the second adhesive layer,
wherein the third structure includes:
a third insulating substrate, a lower surface of which is bonded to an upper surface of the first interconnect and an upper surface of the second interconnect through a third adhesive layer; and
a third interconnect disposed on an upper surface of the third insulating substrate, and
wherein the first interconnect member is a part of a path that electrically connects the second electrode and the third interconnect, and
the second interconnect member is a part of a path that electrically connects the fourth electrode and the first interconnect.

2. The semiconductor apparatus according to claim 1, wherein the first interconnect member includes a first region capable of vertical electrical connection with the third structure,
wherein a first conductive member is disposed on the first region, and
wherein a lower surface of the first conductive member is electrically connected to the first interconnect member via a conductive adhesive layer, and an upper surface of the first conductive member is electrically connected to the third interconnect through a third via interconnect extending through the third insulating substrate and the third adhesive layer.

3. The semiconductor apparatus according to claim 2, wherein the first structure has a through hole extending through the first insulating substrate and the first adhesive layer,
wherein the through hole is aligned with the first region in plan view, and
wherein the first conductive member is located in the through hole in plan view.

4. The semiconductor apparatus according to claim 2, wherein a thickness of the first conductive member is equal to an overall thickness of the first structure and an overall thickness of the second structure.

5. The semiconductor apparatus according to claim 2, wherein the first conductive member is disposed between the first semiconductor device and the second semiconductor device, which are adjacent to each other.

6. The semiconductor apparatus according to claim 1, wherein the second interconnect member includes a second region capable of vertical electrical connection with the first structure,
wherein a second conductive member is disposed on the second region, and
wherein a lower surface of the second conductive member is electrically connected to the second interconnect member via a conductive adhesive layer, and an upper surface of the second conductive member is electrically connected to the first interconnect through a fourth via interconnect extending through the first insulating substrate and the first adhesive layer.

7. The semiconductor apparatus according to claim 6, wherein a thickness of the second conductive member is equal to a thickness of the second semiconductor device.

8. The semiconductor apparatus according to claim 6, wherein the second conductive member is disposed between the first semiconductor device and the second semiconductor device, which are adjacent to each other.

9. The semiconductor apparatus according to claim 1, wherein directions of current flow are opposite between the first interconnect member and the first interconnect.

10. The semiconductor apparatus according to claim 1, wherein directions of current flow are opposite between the third interconnect and each of the second interconnect member and the second interconnect.
